(19) United States
(12) Patent Application Publication
(10) Pub. No.: US 2022/0359525 A1
(43) Pub. Date: Nov. 10, 2022

(54) MEMORY DEVICE AND METHOD OF FORMING THE SAME

(71) Applicant: Winbond Electronics Corp., Taichung City (TW)

(72) Inventors: Chun-Sheng Yang, Taichung City (TW); Hsing-Hao Chen, Taichung City (TW)

(73) Assignee: Winbond Electronics Corp., Taichung City (TW)

(21) Appl. No.: 17/580,610

(22) Filed: Jan. 20, 2022

(30) Foreign Application Priority Data
May 6, 2021 (TW) 110116393

(51) Int. Cl. H01L 27/108

(52) U.S. Cl. CPC H01L 27/10814; H01L 27/10891; H01L 27/10885; H01L 27/10888

(57) ABSTRACT

Provided is a memory device including a substrate, a plurality of bit-line structures, a plurality of bit-line contacts, and a plurality of protective structures. The substrate has a plurality of active areas. The plurality of bit-line structures are disposed on the substrate in parallel along a X direction. The plurality of bit-line contacts are respectively disposed at overlaps of the plurality of bit-line structures and the plurality of active areas, and electrically connect the plurality of bit-line structures and the plurality of active areas. The plurality of protective structures are disposed at least on a first sidewall and a second sidewall of the plurality of bit-line contacts. A method of forming a memory device is also provided.

### CROSS-REFERENCE TO RELATED APPLICATION

This application claims the priority benefit of Taiwan application serial no. 110116393, filed on May 6, 2021. The entirety of the above-mentioned patent application is hereby incorporated by reference herein and made a part of this specification.

### BACKGROUND OF THE INVENTION

### Field of the Invention

The present invention relates to a memory device and a method of forming the same.

### Description of Related Art

A dynamic random access memory (DRAM) is a volatile memory formed by a plurality of memory cells. Specifically, each memory cell is mainly composed of a transistor and a capacitor controlled by the transistor, and the memory cells are electrically connected with one another through word lines and bit lines. In order to improve the integration of DRAM to increase the operating speed of the device and to meet the consumers' demand for miniaturization of electronic devices, buried word line DRAM has been developed in recent years for the aforementioned purposes.

With development of technology, electronic products are developed to have design features of lightness, slimness, shortness and smallness. In this case, the critical dimension of the DRAM is also reduced, which result in many challenges for the DRAM process. For example, when the bit-line contact opening is formed in the silicon substrate, the Si residue will remain in the corner of the active area, thereby causing the short circuit between the capacitor contact and the bit-line contact. Alternatively, when defining the bit-line contact, the poly-Si residue will also remain in the corner of the active area, thereby causing the short circuit between the capacitor contact and the bit-line contact.

### SUMMARY OF THE INVENTION

The invention provides a memory device including a substrate, a plurality of bit-line structures, a plurality of bit-line contacts, and a plurality of protective structures. The substrate has a plurality of active areas. The plurality of bit-line structures are disposed on the substrate in parallel along a X direction. The plurality of bit-line contacts are respectively disposed at overlaps of the plurality of bit-line structures and the plurality of active areas, and electrically connect the plurality of bit-line structures and the plurality of active areas. The plurality of protective structures are disposed at least on a first sidewall and a second sidewall of the plurality of bit-line contacts.

The invention provides a method of forming a memory device including: providing a substrate having a plurality of active areas; forming a plurality of buried word lines in the substrate, wherein the plurality of buried word lines extend along a Y direction and pass through the plurality of active areas; forming a first opening between two adjacent buried word lines to expose a corresponding active area; forming a protective layer to cover a sidewall of the first opening; forming a conductive material in the first opening; forming a plurality of bit-line structures on the substrate, wherein the plurality of bit-line structures extend along a X direction and cover a first portion of the conductive material; performing a first etching process to remove a second portion of the conductive material that is uncovered by the plurality of bit-line structures, so that the first portion of the conductive material forms a bit-line contact and a second opening is formed between the protective layer and the bit-line contact; performing a second etching process to remove a portion of the protective layer that uncovered by the plurality of bit-line structures, so that a remaining portion of the protective layer forms a plurality of protective structures and the second opening is enlarged to form a third opening; and forming a dielectric layer in the third opening.

The invention provides another method of forming a memory device including: providing a substrate having a plurality of active areas; forming a plurality of buried word lines in the substrate, wherein the plurality of buried word lines extend along a Y direction and pass through the plurality of active areas; forming a first opening between two adjacent buried word lines to expose a corresponding active area; forming a protective structure to cover a sidewall of the first opening; forming a conductive material in the first opening; forming a plurality of bit-line structures on the substrate, wherein the plurality of bit-line structures extend along a X direction and cover a first portion of the conductive material; removing a second portion of the conductive material that is uncovered by the plurality of bit-line structures, so that the first portion of the conductive material forms a bit-line contact and a second opening is formed between the protective structure and the bit-line contact; and forming a dielectric layer in the second opening.

Based on above, in the embodiment of the present invention, the protective structure and the dielectric layer surround the bit-line contact in a form of an enclosed path to electrically isolate the bit-line contact from the capacitor contact, and avoid the short circuit between the bit-line contact and the capacitor contact, thereby improving the reliability of the memory device.

### BRIEF DESCRIPTION OF THE DRAWINGS

FIG. 1 is a schematic top view of a memory device according to an embodiment of the invention.

FIG. 2A to FIG. 2E are schematic top views of a manufacturing process of a memory device according to a first embodiment of the invention.

FIG. 3A to FIG. 3E are schematic cross-sectional views of a manufacturing process of the memory device along a line I-I depicted in FIG. 2A, respectively.

FIG. 3F to FIG. 3J are schematic cross-sectional views of a manufacturing process of the memory device along a line I-I depicted in FIG. 2B to FIG. 2E, respectively.

FIG. 4A to FIG. 4D are schematic cross-sectional views of a manufacturing process of the memory device along a line II-II depicted in FIG. 2B to FIG. 2E, respectively.

FIG. 4E to FIG. 4G are schematic cross-sectional views of the subsequent manufacturing process of the memory device depicted in FIG. 4D, respectively.

FIG. 5A to FIG. 5B are schematic top views of a manufacturing process of a memory device according to a second embodiment of the invention.

FIG. 6A to FIG. 6B are schematic cross-sectional views of a manufacturing process of the memory device along a line I-I depicted in FIG. 5A to FIG. 5B, respectively.

FIG. 7A to FIG. 7B are schematic cross-sectional views of a manufacturing process of the memory device along a line II-II depicted in FIG. 5A to FIG. 5B, respectively.

FIG. 7C to FIG. 7E are schematic cross-sectional views of the subsequent manufacturing process of the memory device depicted in FIG. 7B, respectively.

### DESCRIPTION OF THE EMBODIMENTS

The memory device described in the following embodiment is taken a dynamic random access memory (DRAM) as an example, but the invention is not limited thereto.

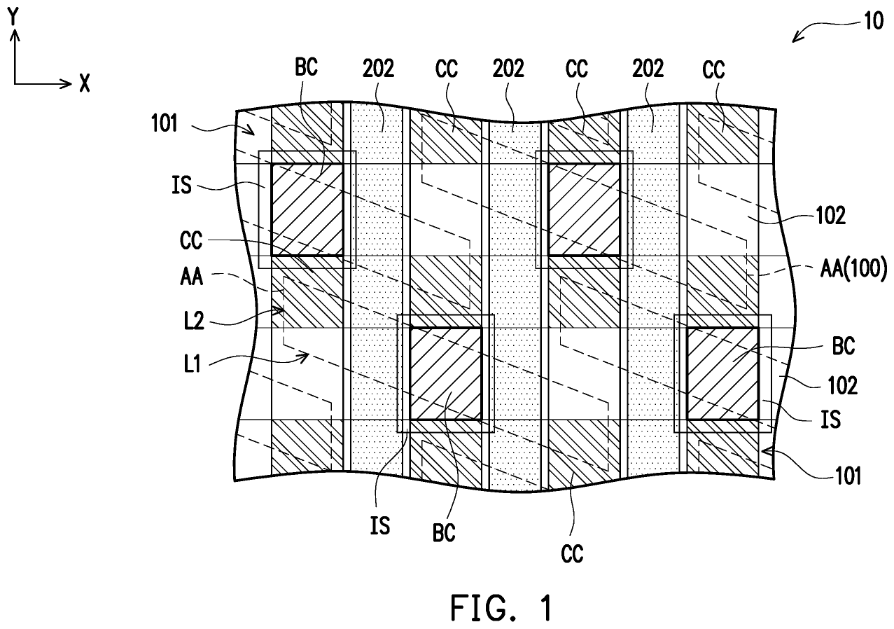

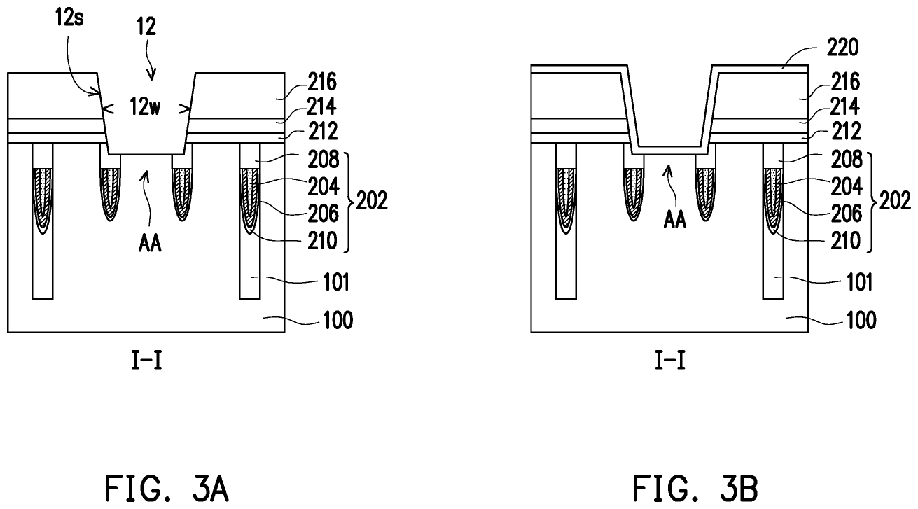

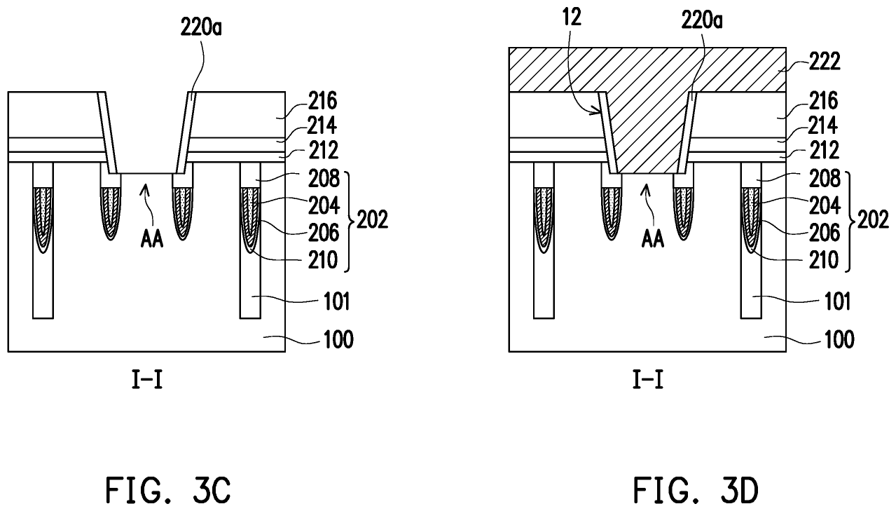

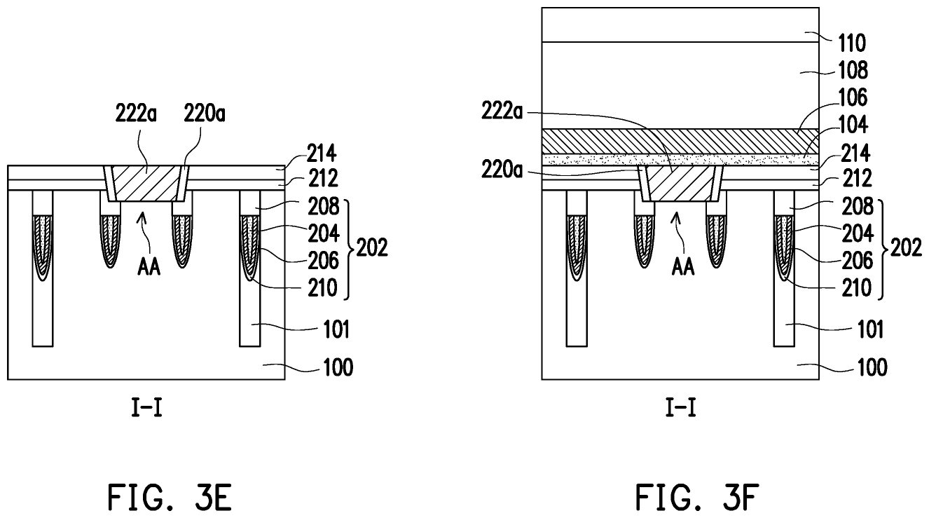

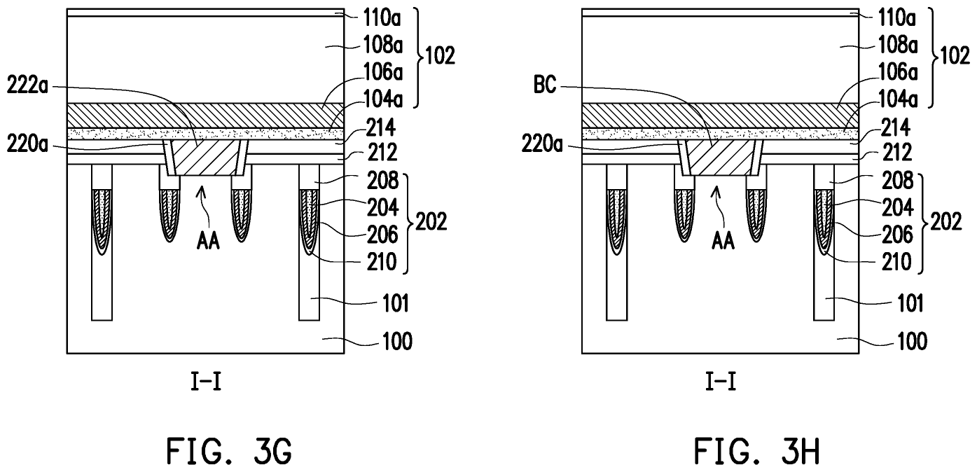

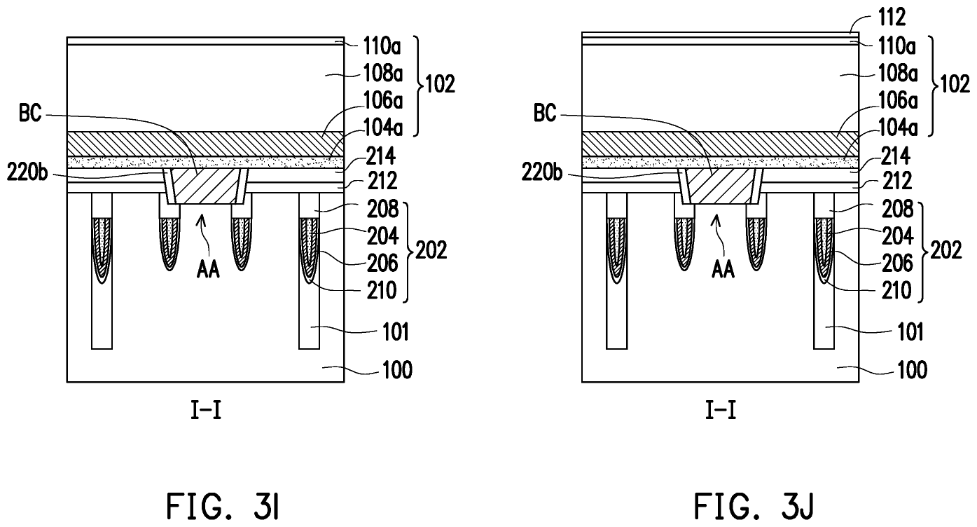

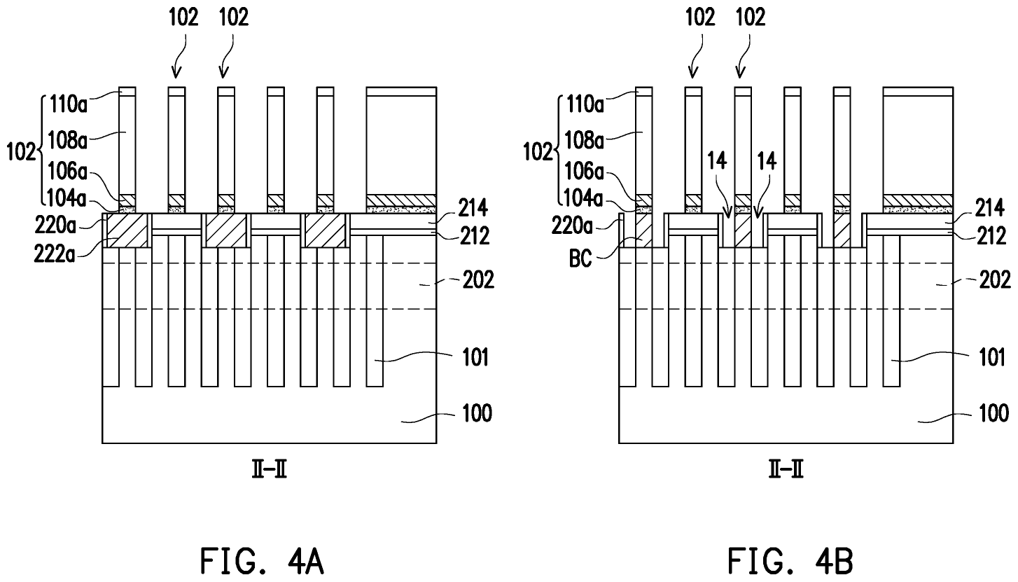

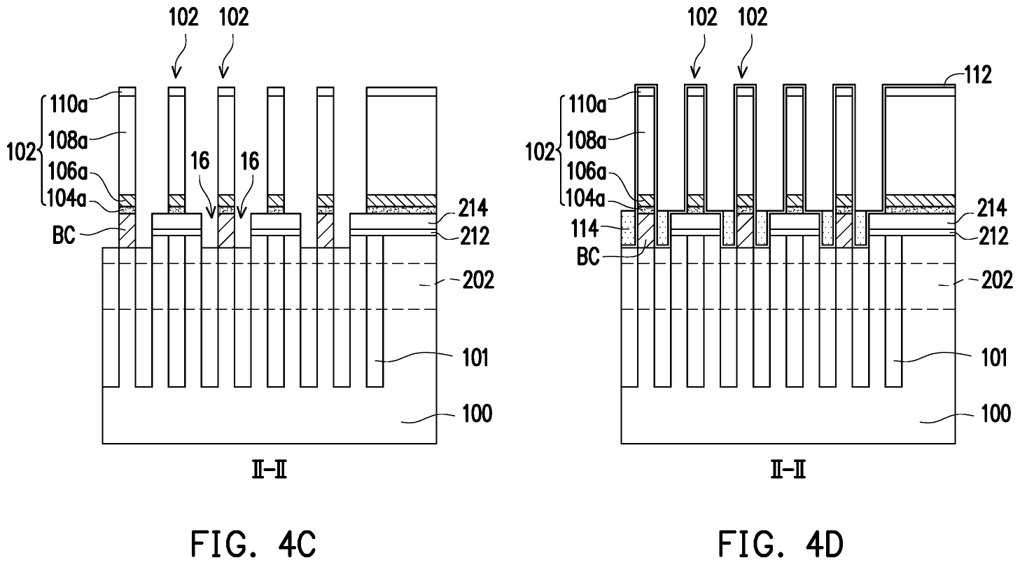

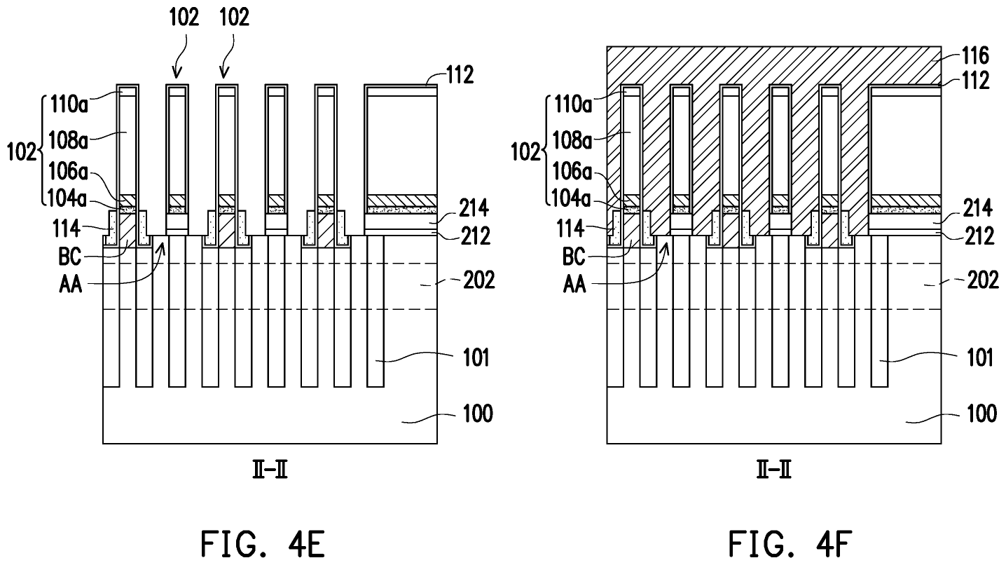

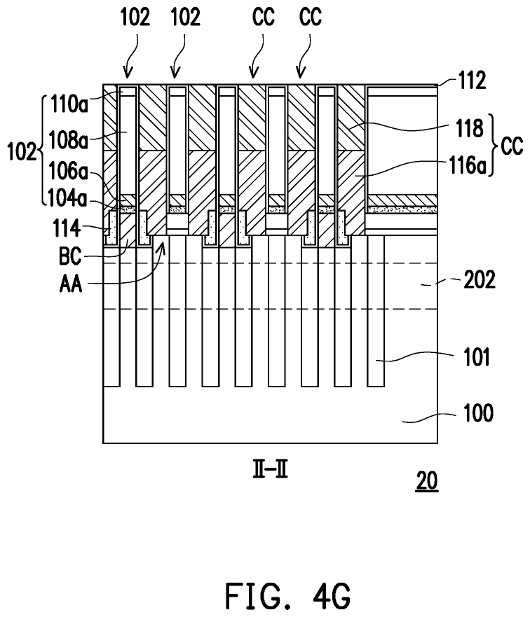

Referring to FIG. 1, the present embodiment provides a memory device 10 including: a substrate 100, a plurality of isolation structures 101, a plurality of active areas AA, a plurality of bit-line structures 102, a plurality of buried word lines 202, a plurality of capacitor contacts CC, a plurality of bit-line contacts BC, and a plurality of electrical insulation structure IS. For clarity of the figure, FIG. 1 only shows the above-mentioned components, and other structures may refer to the subsequent cross-sectional views of FIGS. 3A to 3J and FIGS. 4A to 4G.

As shown in FIG. 1, the substrate 100 includes the plurality of active areas AA. The active areas may be formed by forming the isolation structures 101 in the substrate 100 to define the substrate 100 as the plurality of active areas AA. In other words, one isolation structures 101 is provided between two adjacent active areas. In one embodiment, only one memory cell is formed on one active area AA, and each memory cell is separated by the isolation structures 101, so as to effectively reduce the interference issue among the memory cells.

The bit-line structures 102 are located on the substrate 100 and across the active areas AA. In one embodiment, the bit-line structures 102 extend along a X direction and are arranged with each other along a Y direction. The buried word lines 202 are located in the substrate 100. The buried word lines 202 extend along the Y direction and are arranged with each other along the X direction. In the embodiment, the X direction and the Y direction are substantially perpendicular to each other.

Each active area AA has a long side L1 and a short side L2, and the long side L1 spans the corresponding two buried word lines 202 and one bit-line structure 102. An overlap of each active area AA and its corresponding bit-line structure 102 has a bit-line contact BC. In this case, the bit-line contacts BC may be used to electrically connect the bit-line structures 102 and the doped regions (not shown) in the corresponding active areas AA. The doped region may be located between two buried word lines 202.

The capacitor contacts CC are respectively disposed in the space surrounded by the buried word lines 202 and the bit-line structures 102. In detail, the capacitor contacts CC are respectively disposed on the two terminals of the long side L1 of the active areas AA, which may be electrically connected to the active areas AA and subsequently formed capacitors (not shown). In addition, although the capacitor contacts CC are shown in a rectangular shape in FIG. 1, the actually formed contacts is slightly represented in a circular shape and sizes thereof may be designed based on process requirements.

It should be noted that, as shown in FIG. 1, the electrical insulation structure IS may laterally surround the sidewall of the bit-line contacts BC in a form of an enclosed path to electrically isolate the bit-line contacts BC from the capacitor contacts CC and avoid the short circuit between the bit-line contacts BC and the capacitor contacts CC, thereby improving the reliability of the memory device 10. Although the electrical insulation structure IS shown in FIG. 1 has a square ring layout, the present invention is not limited thereto. The electrical insulation structure IS may also be applied to other suitable layouts, such as a circular ring layout, an elliptical ring layout, and so on.

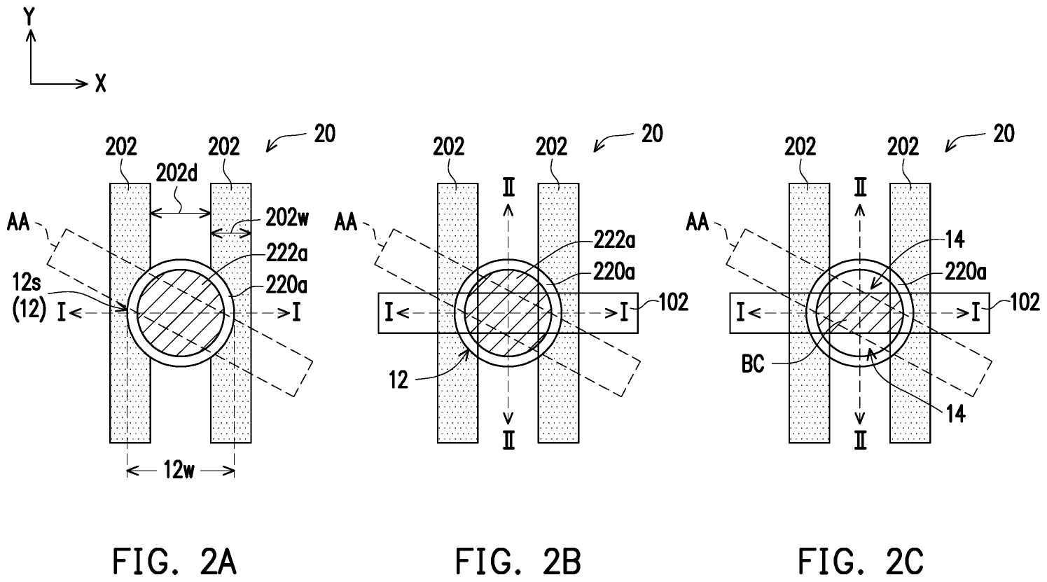

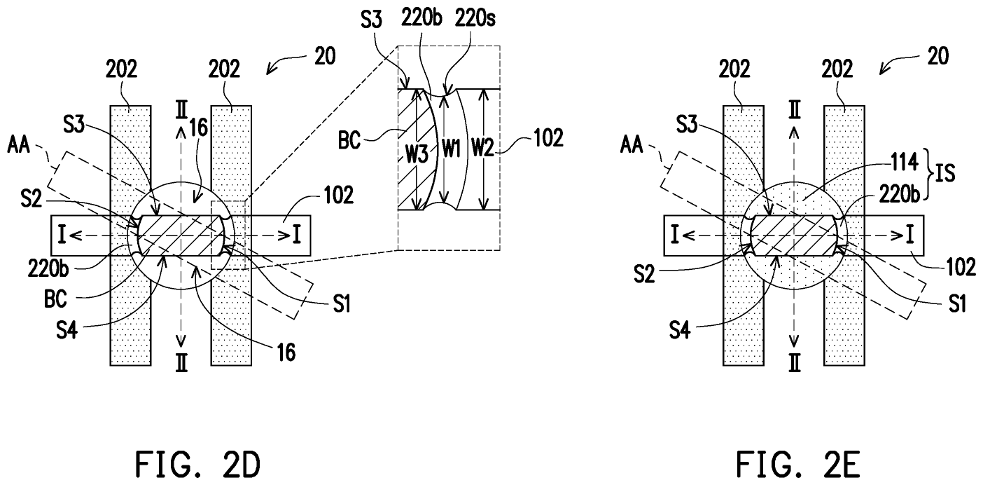

FIG. 2A to FIG. 2E are schematic top views of a manufacturing process of a memory device according to a first embodiment of the invention. FIG. 3A to FIG. 3E are schematic cross-sectional views of a manufacturing process of the memory device along a line I-I depicted in FIG. 2A, respectively. FIG. 3F to FIG. 3J are schematic cross-sectional views of a manufacturing process of the memory device along a line I-I depicted in FIG. 2B to FIG. 2E, respectively. FIG. 4A to FIG. 4D are schematic cross-sectional views of a manufacturing process of the memory device along a line II-II depicted in FIG. 2B to FIG. 2E, respectively. FIG. 4E to FIG. 4G are schematic cross-sectional views of the subsequent manufacturing process of the memory device depicted in FIG. 4D, respectively.

The present embodiment provides a method of forming a memory device 20, which includes the following steps. First, referring to FIG. 3A, an initial structure is provided to include a substrate 100, a plurality of isolation structures 101, and a plurality of buried word lines 202. The substrate 100 may be, for example, a semiconductor substrate, a semiconductor compound substrate, or a semiconductor substrate (SOI) on an insulating layer. In the embodiment, the substrate 100 is a silicon substrate.

As shown in FIG. 3A, the isolation structures 101 are disposed in substrate 100 to divide the substrate 100 into a plurality of active areas AA. The isolation structures 101 include a dielectric material which may be silicon oxide, silicon nitride, or a combination thereof. In addition, the isolation structures 101 may include a single-layered structure, a bi-layered structure, or a multi-layered structure. For example, the isolation structures 101 may include a first isolation layer and a second isolation layer lining the first isolation layer to separate the first isolation layer from the substrate 100. The first isolation layer may be a silicon nitride layer, and the second isolation layer may be a thermal oxide layer. In alternative embodiments, the isolation structures 101 may be a shallow trench isolation structure (STI), for example.

As shown in FIG. 3A, each buried word line 202 includes a conductive layer 204, a barrier layer 206, a sealing layer 208, and a gate dielectric layer 210. The gate dielectric layer 210 wraps the surface of the conductive layer 204 to electrically isolate the conductive layer 204 from the substrate 100. The barrier layer 206 is located between the conductive layer 204 and the gate dielectric layer 210. The sealing layer 208 covers the top surface of the conductive layer 204, the top surface of the barrier layer 206, and the top surface of the gate dielectric layer 210. The conductive layer 204 may be regarded as a gate, and a material of the conductive layer 204 may include a metal material, such as W. A material of the barrier layer 206 may include a barrier metal material, such as Ti, TiN, Ta, TaN, or a combination thereof. A material of the gate dielectric layer 210 may include a dielectric material, such as silicon oxide. A material of the sealing layer 208 may include a dielectric material, such as silicon nitride. In the embodiment, the sealing layer 208 and the gate dielectric layer 210 may have different dielectric materials.

In addition, the initial structure further includes a silicon oxide layer 212, a silicon nitride layer 214, and a silicon oxide layer 216. In detail, the silicon oxide layer 212 is disposed on the substrate 100 and extends to cover the top surface of the sealing layer 208. The silicon nitride layer 214 is disposed on the silicon oxide layer 212. The silicon oxide layer 216 is disposed on the silicon nitride layer 214, so that the silicon nitride layer 214 is located between the silicon oxide layer 212 and the silicon oxide layer 216.

After the initial structure is formed, an opening 12 (also referred to as a first opening) is formed between two adjacent buried word lines 202, as shown in FIG. 3A. Specifically, the opening 12 penetrates through the silicon oxide layer 216, the silicon nitride layer 214, and the silicon oxide layer 212 to expose the active areas AA. In one embodiment, the opening 12 also penetrates through a portion of the sealing layer 208. The opening 12 corresponds to the position of the bit-line contacts BC illustrated in FIG. 1. In one embodiment, a width 12w of the opening 12 is greater than a distance 202d between two adjacent buried word lines 202, as shown in FIG. 2A. A sidewall 12s of the opening 12 may exceed half of the width 202w of the corresponding buried word lines 202. In other words, the width 12w of the opening 12 may be greater than a sum of the width 202w of the word line 202 and the distance 202d between two adjacent buried word lines 202. In this case, a contact area between the subsequently formed bit-line contacts BC (as shown in FIG. 2D) and the active areas AA may be enlarged, thereby reducing the resistance there-between.

Referring to FIG. 3B, after the opening 12 is formed, a protective material 220 is formed on the substrate 100. Specifically, the protective material 220 conformally covers the surface of the opening 12 and the top surface of the silicon oxide layer 216. The protective material 220 may includes a dielectric material, such as silicon oxide, silicon nitride, silicon oxynitride, or a combination thereof. The protective material 220 may be formed by an atomic layer deposition (ALD) method, a chemical vapor deposition (CVD) method, or the like. It should be noted that, when the opening 12 is formed, the silicon residue generated by etching the substrate 100 will remain in the corner of the opening 12. The said silicon residue will cause the short circuit between the subsequently formed bit-line contacts BC and capacitor contacts CC (as shown in FIG. 4G). In the embodiment, the protective material 220 covering the opening 12 can effectively block the silicon residue to electrically isolate the bit-line contacts BC from the capacitor contacts CC.

Referring to FIG. 3C, an etching process is performed to remove a portion of the protective material 220, thereby exposing the active areas AA and forming a protective layer 220a. In one embodiment, the etching process includes a dry etching process, such as a reactive ion etching (RIE) process. In this case, the protective layer 220a may be formed on the sidewall 12s of the opening 12 in a form of a spacer.

Referring to FIG. 3D, a conductive material 222 is formed to fill in the opening 12 and extend to cover the top surface of the silicon oxide layer 216. The conductive material 222 may include doped polysilicon or silicon germanium. The doped polysilicon may be, for example, polysilicon doped with N-type dopants (such as phosphorous), which can effectively reduce the resistance between the conductive material 222 and the active areas AA. The conductive material 222 may be formed by a chemical vapor deposition (CVD) method, an epitaxial growth method, or the like.

Referring to FIG. 3E, an etching back process is performed to remove a portion of the conductive material 222, the silicon oxide layer 216 and a portion of the protective layer 220a, thereby exposing the silicon nitride layer 214 and forming the conductive layer 222a. After the etching back process is performed, as shown in FIG. 2A, the protective layer 220a laterally surrounds the sidewall of the conductive layer 222a in a form of an enclosed path. In addition, a chemical mechanical polishing (CMP) process may be performed to form the conductive layer 222a. In this case, the protective layer 220a, the conductive layer 222a, and the silicon nitride layer 214 may have flush top surfaces.

Referring to FIG. 3F, a barrier layer 104, a bit line 106, a cap layer 108, and a mask layer 110 are sequentially formed on the substrate 100. A material of the barrier layer 104 includes a barrier metal material, which may be Ti, TiN, Ta, TaN, or a combination thereof, for example. A material of the bit line 106 may be a metal material, which may be W, for example. In addition, there may also be a thin metal silicide layer between the barrier layer 104 and the bit line 106, such as silicon tungsten (WSiₓ). A material of the cap layer 108 may be silicon nitride. A material of the mask layer 110 may be silicon oxide, carbon, silicon oxynitride, or a combination thereof. In the embodiment, the mask layer 110 may be a hard mask layer with a multi-layered structure, but the present invention is not limited thereto.

Referring to FIG. 2B, FIG. 3G, and FIG. 4A, the barrier layer 104, the bit line 106, the cap layer 108, and the mask layer 110 are patterned to form a plurality of bit-line structures 102. Specifically, each bit-line structure 102 includes a barrier layer 104a, a bit line 106a, a cap layer 108a, and a mask layer 110a from bottom to top. As shown in the top view of FIG. 2B, the bit-line structures 102 extend along the X direction and across the active areas AA and two buried word lines 202. As shown in the cross-sectional view of FIG. 3G and FIG. 4A, the bit-line structures 102 may be electrically connected to the substrate 100 (or active areas AA) through the conductive layer 222a.

Referring to FIG. 2C, FIG. 3H, and FIG. 4B, a first etching process is performed to remove a portion of the conductive layer 222a that is not covered by the bit-line structures 102, so that a remaining portion of the conductive layer 222a forms the bit-line contacts BC. In this case, the opening 14 (also referred to as the second opening) may be formed between the protective layer 220a and the bit-line contacts BC, as shown in FIG. 2C and FIG. 4B. In one embodiment, the first etching process includes a dry etching process, a wet etching process, or a combination thereof. In the embodiment, there is a high etching selectivity between the conductive layer 222a and the protective layer 220a. That is, in the first etching process, an etching rate of the conductive layer 222a is greater than an etching rate of the protective layer 220a. Therefore, after the first etching process is performed, the exposed conductive layer 222a is completely removed, while the exposed protective layer 220a still remains.

It should be noted that, during the first etching process, the polysilicon residue generated by etching the conductive layer 222a will remain in the corner of the opening 14. The said polysilicon residue will cause the short circuit between the subsequently formed bit-line contacts BC and capacitor contacts CC (as shown in FIG. 4G). In the embodiment, the protective layer 220a laterally surrounds the opening 14, which can effectively block the polysilicon residue to electrically isolate the bit-line contacts BC from the capacitor contacts CC.

Referring to FIG. 2D, FIG. 3I, and FIG. 4C, a second etching process is performed to remove a portion of the protective layer 220a that is not covered by the bit-line structures 102, so that a remaining portion of the protective layer 220a forms a plurality of protective structures 220b. In this case, the opening 14 may be enlarged to form an opening 16 (also referred to as a third opening). As shown in FIG. 2D and FIG. 4C, the protective structures 220b are respectively disposed on a first sidewall S1 and a second sidewall S2 of the bit-line contact BC, and the opening 16 exposes a third sidewall S3 and a fourth sidewall S4 of the bit-line contact BC. The protective structures 220b extend from the first sidewall S1 and the second sidewall S2 of the bit-line contact BC to the corresponding buried word lines 202 respectively. In the embodiment, the second etching process may be a wet etching process. Since the protective layer 220a is isotropically etched, the sidewall 220s of the protective structure 220b may be concave from the third sidewall S3 or the fourth sidewall S4 of the bit-line contact BC. In this case, as shown in the enlarged view of FIG. 2D, a width W1 of the protective structure 220b in the Y direction may be less than a width W2 of the bit-line structure 102 in the Y direction, and may be less than a width W3 of the bit-line contact BC in the Y direction. However, the present invention is not limited thereto. In other embodiments, the width of the protective structure 220b in the Y direction may also be equal to the width of the bit-line structure 102 in the Y direction and may be equal to the width of the bit-line contact BC in the Y direction.

Referring to FIG. 2E, FIG. 3J, and FIG. 4D, a liner layer 112 is formed on the substrate 100. Specifically, the liner layer 112 conformally covers the structure illustrated in FIG. 4C to protect the bit-line structures 102, as shown in FIG. 4D. A material of the liner layer 112 may include a dielectric material, which may be silicon oxide, silicon nitride, silicon oxynitride, or a combination thereof. Next, a dielectric layer 114 is formed in the opening 16. The dielectric layer 114 covers the third sidewall S3 and the fourth sidewall S4 of the bit-line contacts BC. In this case, as shown in the top view of FIG. 2E, the dielectric layer 114 and the protective structures 220b may be regarded as the electrical insulation structure IS. The electrical insulation structure IS may laterally surround all the sidewalls of the bit-line contacts BC (i.e., S1, S2, S3, S4) in a form of an enclosed path. Therefore, the electrical insulation structure IS may electrically isolate the bit-line contacts BC from the subsequently formed capacitor contacts CC (as shown in FIG. 4G), and avoid the short circuit between the bit-line contacts BC and the capacitor contacts CC, thereby improving the reliability of the memory device. In alternative embodiments, the electrical insulation structure IS further includes a portion of the liner layer 112 disposed between the dielectric layer 114 and the bit-line contacts BC, and between the dielectric layer 114 and the protective structures 220b. A material of the dielectric layer 114 may include a nitrogen-containing dielectric material, which may be silicon nitride, silicon oxynitride, or a combination thereof.

After the dielectric layer 114 is formed, a plurality of capacitor contacts CC may be formed on the two terminals of the active areas AA. Since the capacitor contacts CC will only appear on the cross section of the line II-II, the subsequent figures only show the cross-sectional views of FIG. 4E to FIG. 4G along the line II-II, and the cross-sectional views along the line I-I are omitted.

After the dielectric layer 114 is formed, as shown in FIG. 4E, by using the bit-line structures 102 as a mask, a portion of the liner layer 112, a portion of the silicon nitride layer 214, a portion of the silicon oxide layer 212, and a portion of the dielectric layer 114 are removed to expose the surface of the active areas AA.

Next, referring to FIG. 4F, a conductive material 116 is formed to fill in the openings between the bit-line structures 102 and cover the top surface of the bit-line structures 102. The conductive material 116 may include polysilicon, and may be formed by a CVD method.

Referring to FIG. 4G, an etching back process is performed to remove a portion of the conductive material 116, so that the top surface of the conductive layer 116a is lower than the top surface of the bit-line structures 102. Afterwards, a metal layer 118 is formed on the conductive layer 116a. A material of the metal layer 118 may be, for example, W, and the formation method thereof may be a physical vapor deposition (PVD) method. In addition, there may also be a thin metal silicide layer between the conductive layer 116a and the metal layer 118, such as silicon tungsten (WSiₓ).

As shown in FIG. 4G, the composite structure of the conductive layer 116a and the metal layer 118 can be regarded as the capacitor contacts CC. The capacitor contacts CC may be disposed on the two terminals of the active areas AA to electrically connect the active areas AA and the subsequently formed capacitors (not shown).

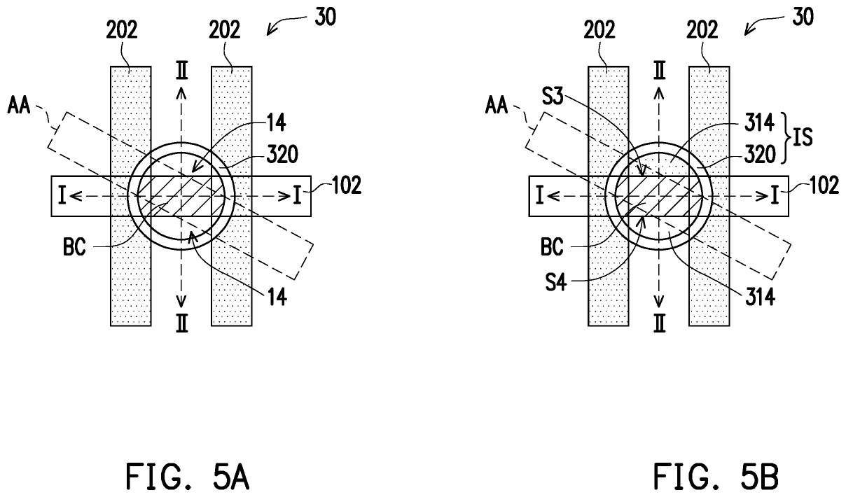

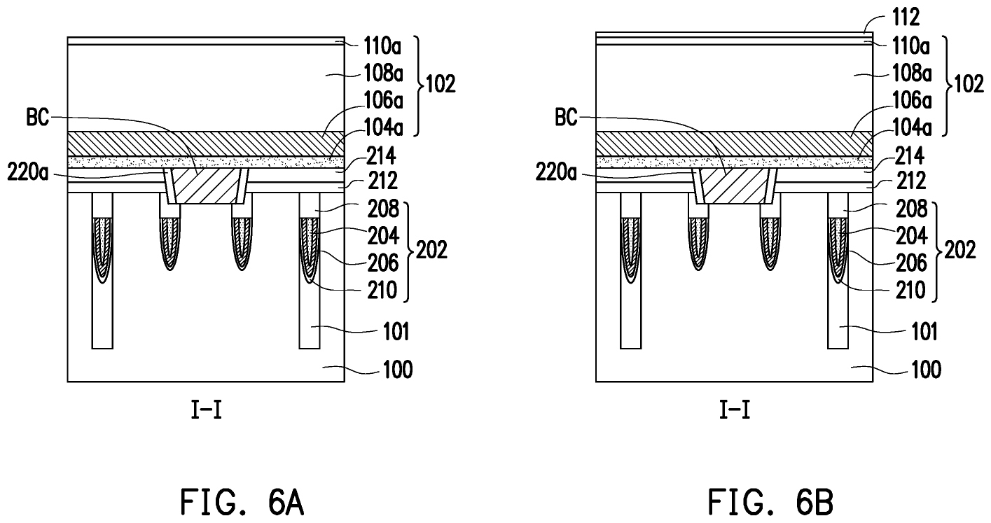

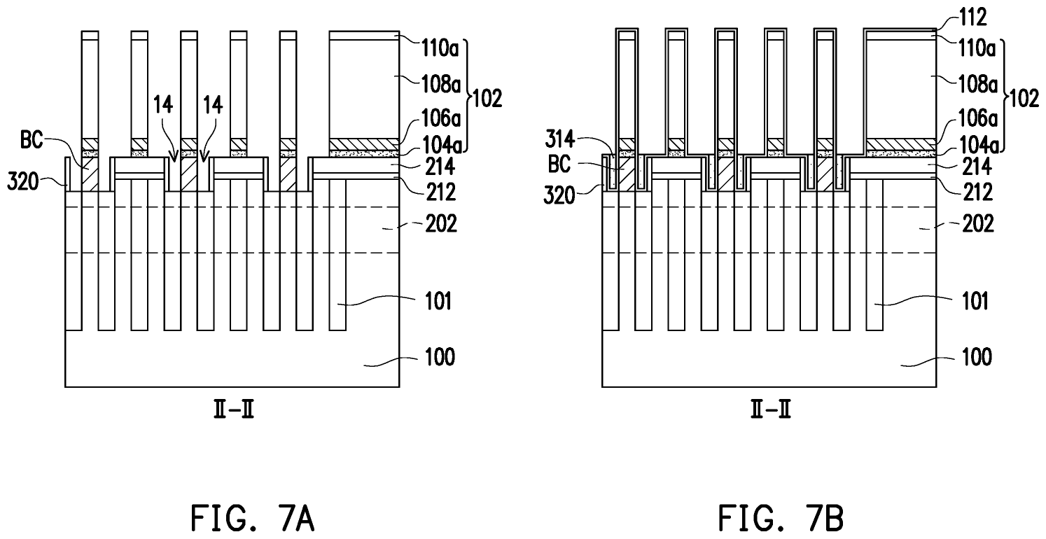

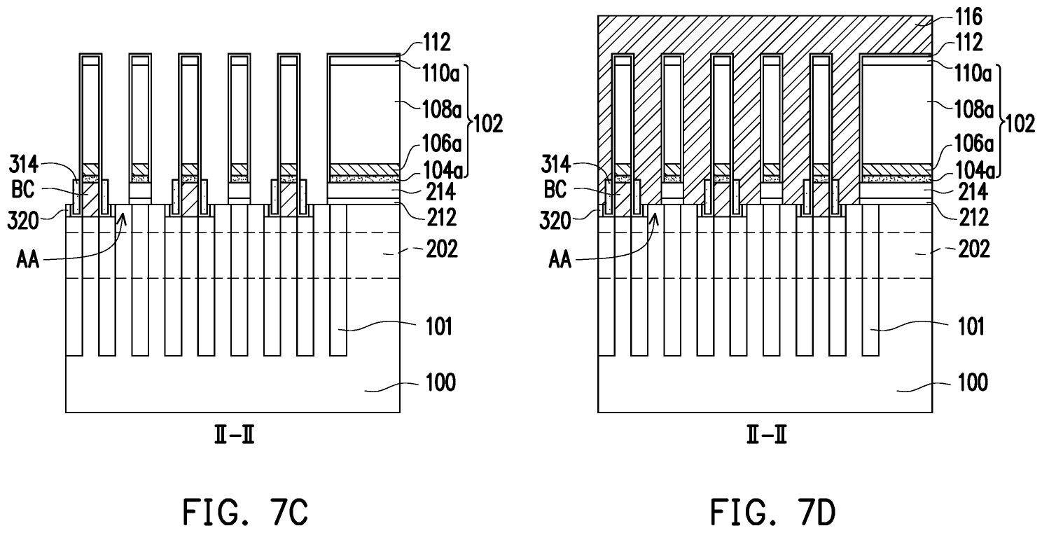

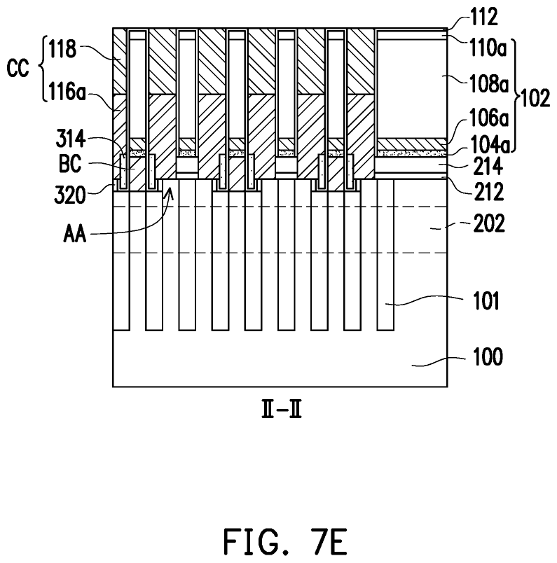

FIG. 5A to FIG. 5B are schematic top views of a manufacturing process of a memory device according to a second embodiment of the invention. FIG. 6A to FIG. 6B are schematic cross-sectional views of a manufacturing process of the memory device along a line I-I depicted in FIG. 5A to FIG. 5B, respectively. FIG. 7A to FIG. 7B are schematic cross-sectional views of a manufacturing process of the memory device along a line II-II depicted in FIG. 5A to FIG. 5B, respectively. FIG. 7C to FIG. 7E are schematic cross-sectional views of the subsequent manufacturing process of the memory device depicted in FIG. 7B, respectively.

The embodiment provides another method of forming a memory device 30. The difference between the memory device 30 and the memory device 20 lies in that the said second etching process is not performed in the method of forming the memory device 30. That is, the memory device 30 retains a ring-shaped protective structure 320 to surround the bit-line contact BC. In addition, the structures of FIG. 5A, FIG. 6A, and FIG. 7A of the second embodiment are the same as the structures of FIG. 2C, FIG. 3H, and FIG. 4B of the first embodiment, and will not be repeated here.

Next, referring to FIG. 5B, FIG. 6B, and FIG. 7B, a dielectric layer 314 is formed in the opening 14. The dielectric layer 314 covers the third sidewall S3 and the fourth sidewall S4 of the bit-line contacts BC, and is disposed between the bit-line contacts BC and the protective structure 320. Specifically, as shown in the top view of FIG. 5B, the protective structure 320 may laterally surround the bit-line contacts BC and the dielectric layer 314 in the form of the enclosed path to achieve the effect of double protection. In this case, the dielectric layer 314 and the protective structure 320 may be regarded as the electrical insulation structure IS, which electrically isolates the bit-line contacts BC from the subsequently formed capacitor contacts CC (as shown in FIG. 7E), and avoids the short circuit between the bit-line contacts BC and the capacitor contacts CC, thereby improving the reliability of the memory device.

It should be noted that, in one embodiment, the materials of the dielectric layer 314 and the protective structure 320 include a nitrogen-containing dielectric material, which may be silicon nitride, silicon oxynitride, or a combination thereof. In the embodiment, the dielectric layer 314 and the protective structure 320 may have the same dielectric material, such as silicon nitride. In this case, the dielectric layer 314 and the protective structure 320 may be used as block structures to avoid excessive etching of forming the capacitor openings, where the excessive etching may cause the short circuit issue caused by the electrical connection of two adjacent capacitor contacts CC.

Afterwards, referring to FIG. 7C, by using the bit-line structures 102 as a mask, a portion of the liner layer 112, a portion of the silicon nitride layer 214, a portion of the silicon oxide layer 212, a portion of the dielectric layer 314, and a portion of the protective structure 320 are removed to expose the surface of active areas AA.

Thereafter, referring to FIG. 7D and FIG. 7E, a plurality of capacitor contacts CC are formed in the openings between the bit-line structures 102 to electrically connect the active areas AA and the subsequently formed capacitors (not shown). The structure, material, and forming method of the capacitor contacts CC illustrated in FIG. 7E are the same as the structure, material, and forming method of the capacitor contacts CC illustrated in FIG. 4G, and have been described in detail in the foregoing embodiments, and will not be repeated here.

In summary, the embodiment of the present invention has the electrical insulation structure composed of the protective structure and the dielectric layer. The said electrical insulation structure may surround the bit-line contact in the form of the enclosed path to electrically isolate the bit-line contact and the capacitor contact and avoid the short circuit between the bit-line contact and the capacitor contact, thereby improving the reliability of the memory device.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A memory device, comprising:
a substrate, having a plurality of active areas;
a plurality of bit-line structures, disposed on the substrate in parallel along a X direction;
a plurality of bit-line contacts, respectively disposed at overlaps of the plurality of bit-line structures and the plurality of active areas, and electrically connecting the plurality of bit-line structures and the plurality of active areas; and
a plurality of protective structures, disposed at least on a first sidewall and a second sidewall of the plurality of bit-line contacts.

2. The memory device according to claim 1, further comprising a plurality of buried word lines disposed in the substrate in parallel along a Y direction, wherein each bit-line contact is disposed between two adjacent buried word lines.

3. The memory device according to claim 2, wherein each protective structure extends from a first sidewall or a second sidewall of a corresponding bit-line contact into a corresponding buried word line.

4. The memory device according to claim 2, wherein each active area is across two buried word lines and one bit-line structure.

5. The memory device according to claim 2, further comprising a plurality of capacitor contacts respectively disposed on two terminals of a long side of the plurality of active areas, and respectively disposed in a space surrounded by the plurality of buried word lines and the plurality of bit-line contacts.

6. The memory device according to claim 2, wherein a width of the plurality of protective structures in the Y direction is less than or equal to a width of the plurality of bit-line contacts in the Y direction.

7. The memory device according to claim 1, further comprising a plurality of dielectric layers respectively disposed on a third sidewall and a fourth sidewall of the plurality of bit-line contacts.

8. The memory device according to claim 1, wherein each protective structure surrounds a first sidewall, a second sidewall, a third sidewall, and a fourth sidewall of a corresponding bit-line contact in a form of an enclosed path.

9. The memory device according to claim 1, wherein the plurality of protective structures comprise a dielectric material, and the dielectric material comprises silicon oxide, silicon nitride, silicon oxynitride, or a combination thereof.

10. The memory device according to claim 1, wherein the plurality of bit-line contacts comprise doped polysilicon or silicon germanium.

11. A method of forming a memory device, comprising:
providing a substrate, having a plurality of active areas;
forming a plurality of buried word lines in the substrate, wherein the plurality of buried word lines extend along a Y direction and pass through the plurality of active areas;
forming a first opening between two adjacent buried word lines to expose a corresponding active area;
forming a protective layer to cover a sidewall of the first opening;
forming a conductive material in the first opening;
forming a plurality of bit-line structures on the substrate, wherein the plurality of bit-line structures extend along a X direction and cover a first portion of the conductive material;
performing a first etching process to remove a second portion of the conductive material that is uncovered by the plurality of bit-line structures, so that the first portion of the conductive material forms a bit-line contact and a second opening is formed between the protective layer and the bit-line contact;
performing a second etching process to remove a portion of the protective layer that uncovered by the plurality of bit-line structures, so that a remaining portion of the protective layer forms a plurality of protective structures and the second opening is enlarged to form a third opening; and
forming a dielectric layer in the third opening.

12. The method of forming the memory device according to claim 11, wherein a width of the first opening is greater than a distance between two adjacent buried word lines.

13. The method of forming the memory device according to claim 11, wherein after performing the second etching process, the plurality of protective structures are respectively disposed on a first sidewall a second sidewall of the bit-line contact, while exposing a third sidewall and a fourth sidewall of the bit-line contact.

14. The method of forming the memory device according to claim 13, wherein after forming the dielectric layer, the dielectric layer covers the third sidewall and the fourth sidewall of the bit-line contact.

15. The method of forming the memory device according to claim 13, wherein each protective structure has a sidewall concave from a third sidewall or a fourth sidewall of a corresponding bit-line contact.

16. The method of forming the memory device according to claim 11, further comprising respectively forming a plurality of capacitor contacts, so that the plurality of capacitor contacts respectively disposed on two terminals of a long side of the plurality of active areas.

17. A method of forming a memory device, comprising:
providing a substrate, having a plurality of active areas;
forming a plurality of buried word lines in the substrate, wherein the plurality of buried word lines extend along a Y direction and pass through the plurality of active areas;
forming a first opening between two adjacent buried word lines to expose a corresponding active area;
forming a protective structure to cover a sidewall of the first opening;
forming a conductive material in the first opening;
forming a plurality of bit-line structures on the substrate, wherein the plurality of bit-line structures extend along a X direction and cover a first portion of the conductive material;
removing a second portion of the conductive material that is uncovered by the plurality of bit-line structures, so that the first portion of the conductive material forms a bit-line contact and a second opening is formed between the protective structure and the bit-line contact; and
forming a dielectric layer in the second opening.

18. The method of forming the memory device according to claim 17, wherein the protective structure surrounds the bit-line contact and the dielectric layer in a form of an enclosed path.

19. The method of forming the memory device according to claim 17, wherein the protective structure comprises a nitrogen-containing dielectric material.

20. The method of forming the memory device according to claim 17, further comprising respectively forming a plurality of capacitor contacts between the plurality of bit-line structures, so that the plurality of capacitor contacts respectively disposed on two terminals of a long side of the plurality of active areas.
